(19) United States
(12) Patent Application Publication
(10) Pub. No.: US 2003/0142739 A1
(43) Pub. Date: Jul. 31, 2003

(54) Digital filter for filtering time-division-multiplexed signal

(76) Inventor: Masahiro Shiozawa, Kanagawa (JP)

Correspondence Address: FISH & RICHARDSON P.C., 1425 K STREET, N.W., 11TH FLOOR, WASHINGTON, DC, 20005-3500, US

(21) Appl. No.: 10/353,977

(22) Filed: Jan. 30, 2003

(30) Foreign Application Priority Data
Jan. 31, 2002 (JP) 23736/2002

(51) Int. Cl. H03K 5/159

(52) U.S. Cl. 375/229

(57) ABSTRACT

A digital filter is provided for simultaneously filtering different components of a time-division-multiplexed signal. The digital filter comprises an odd number of a plurality of taps. A center tap and odd-numbered taps counted from the center tap all have coefficients equal to zero. The remaining taps, i.e., even-numbered taps counted from the center tap have coefficients for defining the filtering characteristic.

### BACKGROUND OF THE INVENTION

The present invention relates to a digital filter for use in simultaneously filtering different components of a time-division multiplexed (TDM) signal, and to a double interpolation circuit in which such a filter is used.

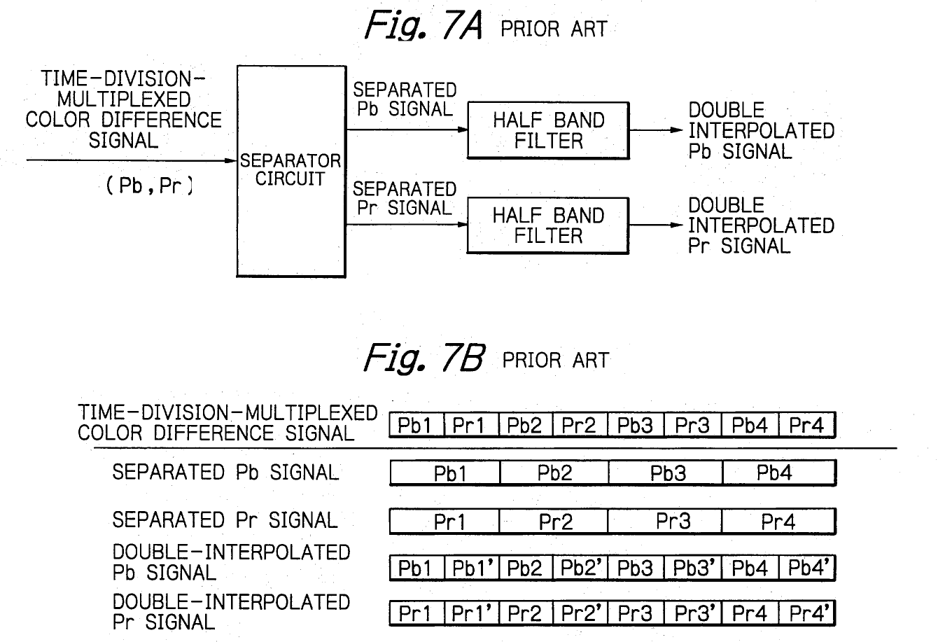

Conventionally, a SDI (serial digital interface) signal is typically transmitted as a 4:2:2 luminance/color difference signal. To generate a 4:4:4 signal from the 4:2:2 signal, it is necessary to double the sampling rate of the color difference signal. To achieve this, a double interpolation circuit as illustrated in FIG. 7A is used. The illustrated double interpolation circuit comprises a separator circuit which receives a video component signal on which color difference signals Pb, Pr are time-multiplexed, and separates the video component signal into a Pb color difference signal (signal A) and a Pr color difference signal (signal B), as shown in FIG. 7B. The respective separated signals A, B are subject to double interpolation by half band filters associated therewith to generate color difference signals having the same sampling rate as the original input video component signal, as illustrated in FIG. 7B. In FIG. 7B, Pb1′, Pb2′ and the like designate interpolation signals of the color difference signal Pb; and Pr1′, Pr2′, and the like designate interpolation signals of the color difference signal Pr.

As illustrated in FIG. 7A, since the double interpolation circuit performs double interpolation of each of separated color difference signals, it is necessary to provide the double interpolation circuit with two half band filters. Specifically, for each component of a time-division multiplexed signal to be digitally filtered a separate digital filter must be provided. This results in a disadvantageous increase in circuit size and mounting area, as well as in cost.

### SUMMARY OF THE INVENTION

To solve the stated problem of the conventional art, it is an object of the present invention to provide a filtering method which is capable of simultaneously filtering different components of a time-division multiplexed signal, and also a digital filter for implementing the filtering method.

It is another object of the present invention to provide a method and circuit for enabling a single digital filter to perform double interpolation of a video component signal.

It is a further object of the present invention to provide a method and circuit for performing double interpolation of a video component signal at relatively low cost.

To achieve the above objects, according to a first aspect of the present invention, a digital filter has a plurality of taps, wherein every (i+1)−th taps from a predetermined tap have coefficients for defining the characteristic of filtering, where i is an arbitrary positive integer, and the remaining taps have coefficients equal to zero. According to the present invention the number i may be equal to one.

According to a second aspect of the present invention, a digital filter has an odd number of a plurality of taps, wherein a center tap, and odd-numbered taps counted from the center tap of the plurality of taps all have coefficients equal to zero, and the rest of the plurality of taps have coefficients which define a characteristic of filtering. According to the present invention, the digital filter receives a first and a second time-division-multiplexed signal sequence as inputs, each of which comprises discrete signal components, and the digital filter can apply the same filtering to each of the first and second signal sequences received thereby to generate, as an output, a first and a second filtered signal sequence in a time division multiplex form. In this instance, filtering may form differential interpolation components of the discrete signal components of each of the signal sequences. Each of the signal sequences may be an SDI signal. Further, the first and second signal sequences may be two color difference signals of a video component signal, respectively.

According to a third aspect of the present invention, a half band filter having an odd number of a plurality of taps is provided, wherein a center tap of the plurality of taps has a coefficient equal to zero.

According to a fourth aspect of the present invention, a double interpolation circuit is provided for generating a first double interpolated signal sequence and a second double interpolated signal sequence from an input signal which comprises a first and a second signal sequence being alternately time-division-multiplexed. Each of the first and second signal sequences comprises discrete signal components. The double interpolation circuit includes a digital filter having an input for receiving the input signal, and an output for generating a filter output on which a first and a second filtered signal sequence are alternately time-division-multiplexed; separating means connected to receive the filter output for separating the first filtered signal sequence and the second filtered signal sequence from the filter output; delay means connected to receive the input signal for generating a delayed input signal; and combining means for combining the first filtered signal sequence with the first signal sequence in the delayed input signal to generate the first double interpolated signal sequence, and for combining the second filtered signal sequence with the second signal sequence in the delayed input signal to generate the second double interpolated signal sequence.

According to a fifth aspect of the present invention, a filtering method is provided for simultaneously filtering an input signal which comprises a first and a second signal sequence being alternately time-division-multiplexed. Each of the first and second signal sequences comprises discrete signal components. The method includes the steps of: providing a digital filter which has an odd number of a plurality of taps, wherein a center tap and odd-numbered taps counted from the center tap of the plurality of taps have coefficients equal to zero, and the rest of the plurality of taps have coefficients for defining a filtering characteristic of the digital filter; and applying the input signal to the digital filter to execute the same filtering on each of the first and second signal sequences to generate a first and a second filtered signal sequence in a time-division multiplexed form to be output from the digital filter.

According to the present invention, the filtering method may further include the step of separating the first and second filtered signal sequences in the time-division multiplexed form to generate the first filtered signal sequence and the second filtered signal sequence. The filtering may form differential interpolation components of the discrete signal components of each of the signal sequences.

According to a sixth aspect of the present invention, a double interpolation method is provided for generating a first double interpolated signal sequence and a second double interpolated signal sequence from an input signal, which comprises a first and a second signal sequence being alternately time-division-multiplexed. Each of the first and second signal sequences comprises discrete signal components. The double interpolation method includes the steps of: applying the input signal to a digital filter for outputting in response to the input signal a filter output comprising a first and a second filtered signal sequence being alternately time-division-multiplexed; separating the filter output into the first filtered signal sequence and the second filtered signal sequence; delaying the input signal to generate a delayed input signal; combining the first filtered signal sequence with the first signal sequence in the delayed input signal to generate the first double interpolated signal sequence; and combining the second filtered signal sequence with the second signal sequence in the delayed input signal to generate the second double interpolated signal sequence.

### BRIEF DESCRIPTION OF THE INVENTION

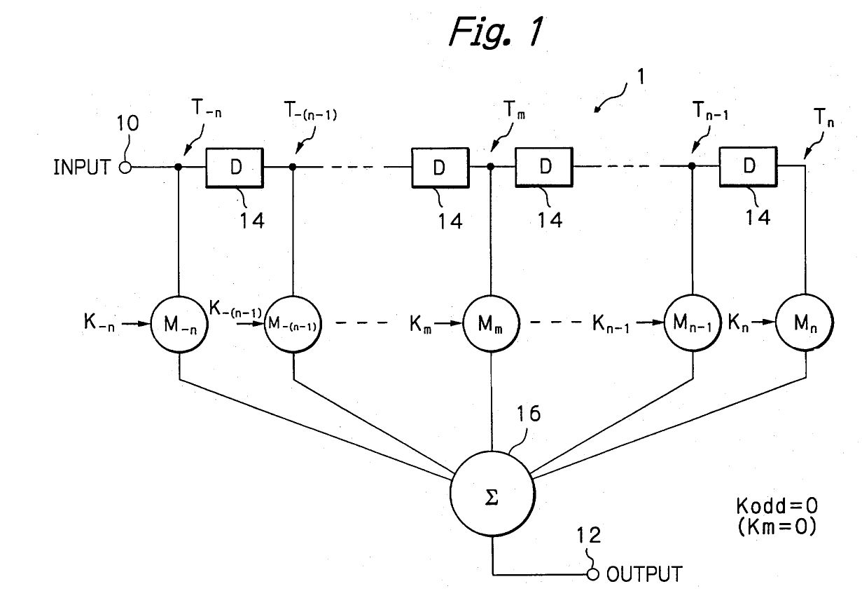

FIG. 1 is a block diagram illustrating the configuration of a time-division-multiplex (TDM) digital filter according to the present invention;

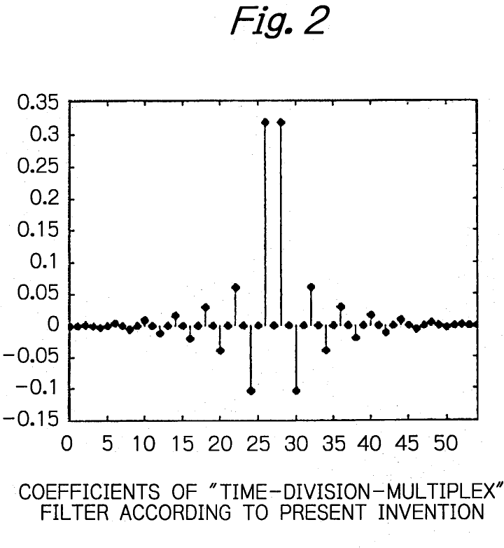

FIG. 2 is a graph showing a sequence of coefficients of the TDM digital filter according to the present invention;

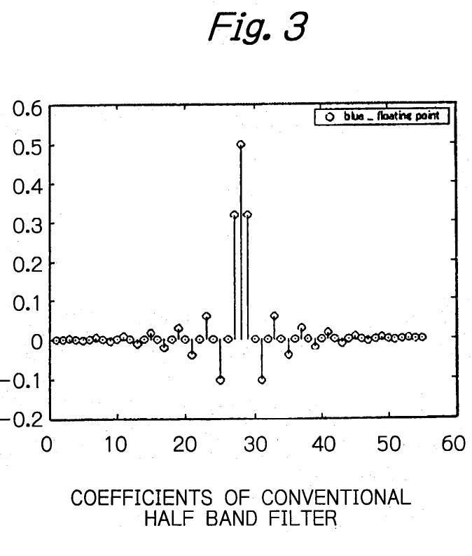

FIG. 3 is a graph showing a sequence of coefficients of a conventional half band filter;

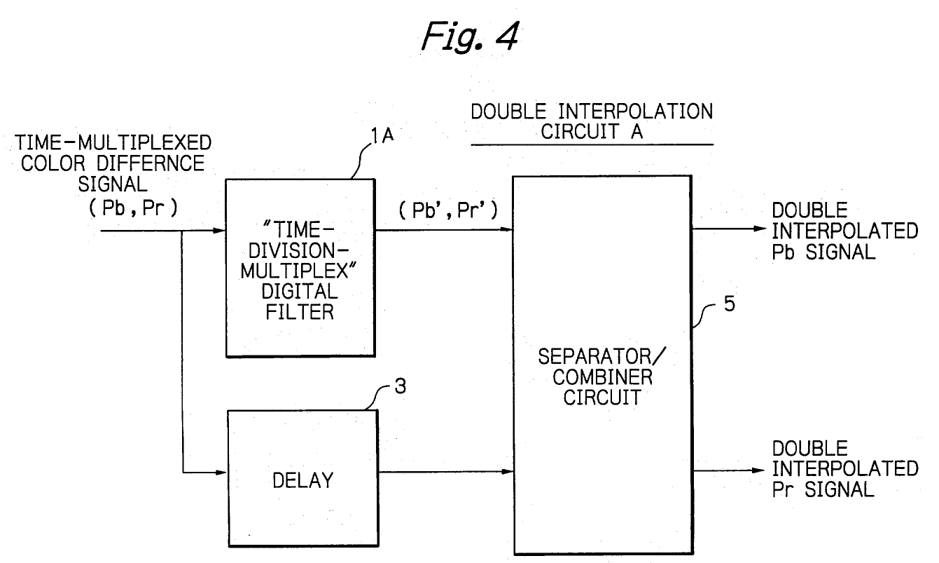

FIG. 4 is a block diagram illustrating one embodiment of a double interpolation circuit which uses the TDM digital filter shown in FIG. 1;

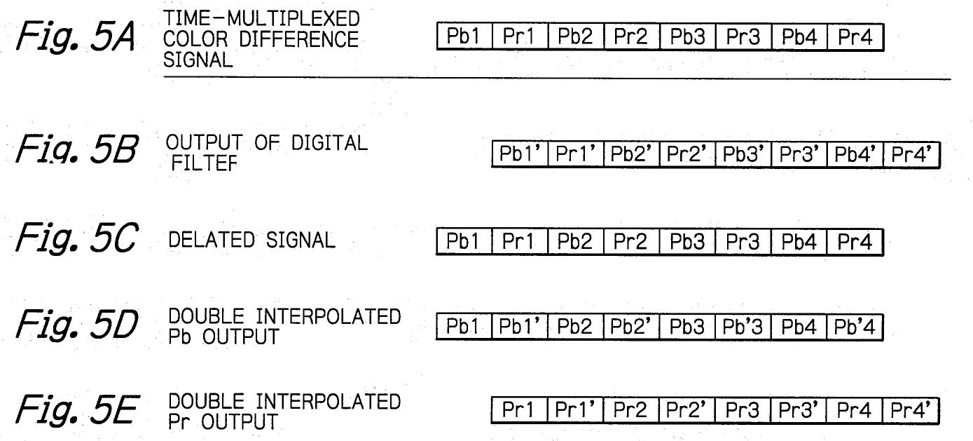

FIGS. 5A to 5E are timing diagrams showing respective signals associated with the double interpolation circuit shown in FIG. 4 for describing the operation thereof;

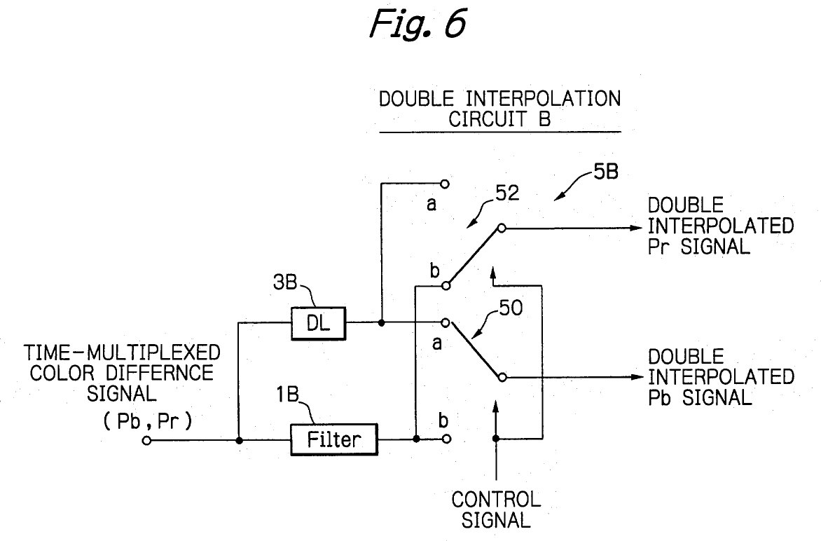

FIG. 6 is a circuit diagram showing a double interpolation circuit which embodies a portion of the double interpolation circuit shown in FIG. 4 in greater detail;

FIG. 7A is a block diagram illustrating a conventional double interpolation circuit; and

FIG. 7B is a diagram showing signals in the double interpolation circuit of FIG. 7A.

### DETAILED DESCRIPTION OF THE INVENTION

In the following, one embodiment of the present invention will be described with reference to several embodiments.

FIG. 1 illustrates the configuration of a digital filter 1 according to the present invention for simultaneously filtering different components of a time-division multiplexed (TDM) signal. The filtering performed by the digital filter 1 simultaneously affects different components of a TDM signal, and is therefore referred to as “time-division multiplexed (TDM) filtering”; and a digital filter having such a function is referred to as “time-division multiplex (TDM) digital filter”.

As illustrated, the TDM digital filter 1, which has a structure similar to a known digital filter, comprises an input terminal 10 for receiving a time-division-multiplexed (TDM) signal; and an output terminal 12 for generating a filtered TDM signal resulting from the TDM filtering applied to the input TDM signal. An example of the TDM signal received at the input terminal 10 is a color difference signal portion (a Pb and a Pr signal component) of an SDI signal which is transmitted as a 4:2:2 luminance/color difference signal (video component signal). The TDM filter 1 also comprises a plurality of taps T₋ₙ - - - T₋₂, Tₘ, T₂ - - - Tn, where Tₘ designates a center tap, T₋₂ designates the second tap counted from the center tap on the input side, and T₂ designates the second tap counted from the center tap on the opposite side of the input 10. The total number X of taps is calculated as 2(n−1)+1=2n−1 which is an odd number. The plurality of taps are connected to each other through a delay 14 which provides a delay of one clock. The plurality of taps are also connected to associated inputs of an adder 16 through X multipliers M₋ₙ - - - M₋₂, Mₘ, M₂ - - - Mₙ associated therewith. Each of the multipliers has an associated coefficient of multiplication coefficients k₋ₙ - - - k₋₂, kₘ, k₂ - - - kₙ. The adder 16 sums received outputs from the respective taps through the multipliers to generate a filtered output at the output terminal 12.

The TDM filter 1 of the present invention performs the TDM filtering on a color difference signal which comprises two signal components Pb, Pr being time-division-multiplexed, so that the center tap and odd-numbered taps counted from the center tap (i.e., . . . k₋₅, k₋₃, kₘ, k₃, k₅, . . . ) have coefficients k_{odd} equal to zero. The remaining taps, i.e., even-numbered taps counted from the center tap (i.e., . . . k₋₄, k₋₂, k₂, k₄, . . . ) have coefficients kₑᵥₑₙ equal to values which define the characteristic of filtering performed on each signal component.

FIG. 2 shows exemplary coefficients of the TDM filter according to the present invention. The filter in the shown example has 55 taps (n=55), where the center tap and odd-numbered taps counted from the center tap all have tap coefficients equal to zero. Therefore, the center tap Tm also has a coefficient equal to zero (kₘ=0). For comparison, FIG. 3 shows a sequence of coefficients of a conventional half band filter. As can be seen from the graph, in the conventional 55-tap filter, odd-numbered taps counted from the center tap all have coefficient equal to zero, except for the center tap. As will be appreciated from a comparison of FIG. 2 with FIG. 3, the TDM filter of the present invention differs from the conventional half band filter in that the center tap also has a coefficient equal to zero. It should be noted that even-numbered taps counted from the center tap have the same coefficients in both FIGS. 2 and 3.

With the sequence of coefficients shown in FIG. 2, upon receipt of a TDM color difference signal at the input terminal 10 in the TDM filter of the present invention, when one of two signal components included in the TDM color difference signal, for example, the Pb component is positioned at the center tap and at odd-numbered taps counted from the center tap, the other signal component, for example, the Pr component is always positioned at even-numbered taps counted from the center tap. Then, the one Pb signal component is not filtered, while the other Pr signal component is filtered. Next, when the TDM color difference signal is shifted one tap to the right, the one Pb signal component is positioned at even-numbered taps counted from the center tap, while the other Pr signal component is positioned at the center tap and odd-numbered taps counted from the center tap. Then, the one Pb signal component is filtered, while the other Pr signal component is not filtered. As the TDM signal is further shifted to the right along the taps, the foregoing two states are repeated, thereby causing a signal component Pb′ generated by filtering the one Pb signal component and a signal component Pr′ generated by filtering the other Pr signal component to alternately appear at the output terminal 12 in time division. In this instance, since the center tap and the odd-numbered taps counted from the center tap all have coefficients equal to zero, filtering on one signal component will not affect filtering on the other signal component. In this manner, TDM filtering on a TDM signal can be implemented by a single digital filter.

Next, one embodiment of a double interpolation circuit A using the TDM filter of FIG. 1 for interpolating a TDM color difference signal will be described with reference to FIG. 4. As illustrated, the double interpolation circuit A comprises a TDM digital filter 1A which has the same configuration as the digital filter of FIG. 1: a delay 3; and a separator/combiner circuit 5. More specifically, the digital filter 1A receives at an input a TDM signal on which time-division-multiplexed are a Pb color difference signal component sequence and a Pr color difference signal component sequence, and generates, at an output, a signal which undergoes TDM filtering. As illustrated in FIG. 2, the digital filter 1A has a filter characteristic which is identical to the conventional half band filter wherein a center tap has a coefficient set to zero, and which generates a differential interpolation component of the Pb component sequence or Pr component sequence. Therefore, the digital filter 1A generates at the output a time-multiplexed form of a differential interpolation component sequence of the Pb signal and a differential interpolation component sequence of the Pr signal. The delay 3, which is connected in parallel with the digital filter 1A, has an input for receiving the TDM color difference signal, like the digital filter 1A, delays the received signal in correspondence to a delay involved in the filtering in the digital filter 1A, and generates a resulting delayed signal at an output. The amount of delay in the delay 3 is chosen to effect appropriate separation/combination of a signal in the subsequent separator/combiner circuit 5, and specifically, is chosen to be one clock less than the delay in the digital filter 1A. The separator/combiner circuit 5 has an input for receiving the output of the digital filter 1A; another input for receiving the output of the delay 3; an output for generating a double interpolated Pb signal; and an output for generating a double interpolated Pr signal. The separator/combiner circuit 5 separates the received filter output and delay output into respective Pb components and Pr components, and combines the Pb components or Pr components together to form the aforementioned double interpolated Pb and Pr signals.

Next, the operation of the double interpolation circuit A in FIG. 4 will be described with reference to FIG. 5. As shown in FIG. 5A, a sequence of Pb components Pb1, Pb2, Pb3, . . . is time-division-multiplexed with a sequence of Pr components Pr1, Pr2, Pr3, . . . such that these components are alternately arranged. Each component comprises one word consisting of ten parallel bits. The digital filter 1A, which receives the color difference signal, generates a filter output which is delayed by a predetermined amount, as shown in FIG. 5B. The filter output includes a sequence of differential interpolation components Pb1′, Pb2′, Pb3′, . . . of the Pb component sequence Pb1, Pb2, Pb3, . . . , and a sequence of differential interpolation components Pr1′, Pr2′, Pr3′, . . . of the Pr component sequence Pr1, Pr2, Pr3, . . . in a time division multiplex form. In other words, the two sequences of differential interpolation components alternately appear at the output of the filter 1A. On the other hand, the delay 3 delivers at the output the original input color difference signal which is delayed but appears at a timing advanced component, i.e., one clock from the filter output. It should be noted that the timings of the signals are not exact in between FIG. 5A and FIGS. 5B to 5E. Next, the separator/combiner circuit 5 extracts the Pb′ component sequence of the filter output and the Pb component sequence of the delay output, and alternately combines the extracted component sequences to form a double interpolated Pb signal which comprises Pb1, Pb1′, Pb2, Pb2′, Pb3, Pb3′,. . . Similarly, the separator/combiner circuit 5 extracts the Pr′ component sequence of the filter output and the Pr component sequence of the delay output, and alternately combines the extracted component sequences to form a double interpolated Pr signal which comprises Pr1, Pr1′, Pr2, Pr2′, Pr3, Pr3′, . . . The signals thus formed are identical to those in the prior art, as can be seen from a comparison with the double interpolated signal shown in FIG. 7B.

Referring next to FIG. 6, description will be made of a double interpolation circuit B which embodies a portion of the double interpolation circuit A in FIG. 4 in greater detail. The double interpolation circuit B comprises a digital filter 1B and a delay 3B similar to the digital filter 1A and delay 3 in FIG. 4, respectively, and a pair of switches 50, 52 which implement a separator/combiner circuit 5B. Each of the switches 50, 52 has an input terminal a connected to the output of the delay 3B; an input terminal b connected to the output of the digital filter 1B; and an output terminal. Each of the switches 50, 52 also has a control input for receiving a control signal for switching to the a side or b side. Thus, the switches 50, 52 are switched to the a side when the control signal is in a first state, thereby causing the switch 50 to pass the output of the delay 3B to its output terminal, and the switch 52 to pass the output of the digital filter 1B to its output terminal. On the other hand, the switches 50, 52 are switched to the b side when the control signal is in a second state reverse to the first state, thereby causing the switch 50 to pass the output of the digital filter 1B to its output terminal and the switch 52 to pass the output of the delay 3B to its output terminal. In this manner, as described above with reference to FIG. 5, the double interpolated Pb signal is generated at the output of the switch 50, while the double interpolated Pr signal is generated at the output of the switch 52.

In the embodiment of the present invention described above in detail, the following modification may be made. First, in the foregoing embodiment, the multipliers associated with the taps having coefficients equal to zero may be omitted, while the delays associated with these taps are retained. In this way, the configuration of the digital filter of the present invention can be made relatively simple. Alternatively, a digital filter having a large number of taps can be implemented by a fewer number of multipliers. Second, in the foregoing embodiment, the digital filter has a filter characteristic identical to that for forming differential interpolation components of the conventional half band filter. In the present invention, however, when different filtering is required for a TDM signal, coefficients can be established such that the digital filter has a filter characteristic corresponding to the filtering.

Third, while the foregoing embodiment has been described in connection with a digital filter configuration for use with a TDM signal on which two signal components are time-division-multiplexed, the present invention can be applied similarly to a signal on which n components are time-division-multiplexed. In this case, a desired filter characteristic is realized using predetermined taps, for example, every (i+1)−th taps from the input terminal side with the first tap from the input terminal side being selected as a starting tap (for example, every n−th taps for a TDM signal comprising n signals (i=n−1)), with the remaining taps provided with coefficients equal to zero, thereby making it possible to simultaneously apply the same filtering to n time-division-multiplexed signals.

As described above, the digital filter according to the present invention can apply the same filtering to each of a plurality of signals included in a TDM signal without separation. Also, since the digital filter can be shared, this is effective in reducing the cost of an overall circuit including the digital filter. In addition, the multipliers can be omitted in the taps of the filter having coefficients equal to zero, thereby further reducing the cost of the digital filter itself. Furthermore, double interpolation of a signal can be simply implemented at low cost, as compared with the prior art.

What is claimed is:

1. A digital filter having a plurality of taps, wherein:
every (i+1)−th taps from a predetermined tap have coefficients for defining the characteristic of filtering, where i is an arbitrary positive integer; and
the remaining taps have coefficients equal to zero.

2. A digital filter according to claim 1, wherein:
said number i is equal to one.

3. A digital filter having an odd number of a plurality of taps, wherein:
a center tap, and odd-numbered taps counted from said center tap of said plurality of taps all have coefficients equal to zero; and
the rest of said plurality of taps have coefficients for defining a characteristic of filtering.

4. A digital filter according to claim 3, wherein:
said digital filter receives a first and a second time-division-multiplexed signal sequence as inputs, each of said signal sequences comprising discrete signal components, and
said digital filter applies the same filtering to each of said first and second signal sequences received thereby to generate as an output a first and a second filtered signal sequence in a time division multiplex form.

5. A digital filter according to claim 4, wherein:
said filtering forms differential interpolation components of the discrete signal components of each said signal sequence.

6. A digital filter according to claim 5, wherein:
each said signal sequence is an SDI signal.

7. A digital filter according to claim 6, wherein:
said first and second signal sequences are two color difference signals (Pb, Pr) of a video component signal, respectively.

8. A half band filter having an odd number of a plurality of taps, wherein:
a center tap of said plurality of taps has a coefficient equal to zero.

9. A double interpolation circuit for generating a first double interpolated signal sequence and a second double interpolated signal sequence from an input signal which comprises a first and a second signal sequence being alternately time-division-multiplexed, each of said first and second signal sequences comprising discrete signal components, said double interpolation circuit comprising:
a digital filter having an input for receiving said input signal, and an output for generating a filter output on which a first and a second filtered signal sequence are alternately time-division-multiplexed;
separating means connected to receive said filter output for separating said first filtered signal sequence and said second filtered signal sequence from said filter output;
delay means connected to receive said input signal for generating a delayed input signal; and
combining means for combining said first filtered signal sequence with said first signal sequence in said delayed input signal to generate said first double interpolated signal sequence, and for combining said second filtered signal sequence with said second signal sequence in said delayed input signal to generate said second double interpolated signal sequence.

10. A double interpolation circuit according to claim 9, wherein:
said plurality of taps of said digital filter include a center tap and odd-numbered taps counted from said center tap, all of which have coefficients equal to zero.

11. A double interpolation circuit according to claim 10, wherein:
said filtering forms differential interpolation components of the discrete signal components of each said signal sequence.

12. A double interpolation circuit according to claim 11, wherein:
each said signal sequence is an SDI signal.

13. A double interpolation circuit according to claim 12, wherein:
said first and second signal sequences are two color difference signals (Pb, Pr) of a video component signal, respectively.

14. A filtering method for simultaneously filtering an input signal which comprises a first and a second signal sequence being alternately time-division-multiplexed, said first and second signal sequences each comprising discrete signal components, said method comprising the steps of:
providing a digital filter, said digital filter having an odd number of a plurality of taps, wherein a center tap and odd-numbered taps counted from said center tap of said plurality of taps have coefficients equal to zero, and the rest of said plurality of taps have coefficients for defining a filtering characteristic of said digital filter;
applying said input signal to said digital filter for executing said same filtering on each of said first and second signal sequences to generate a first and a second filtered signal sequence in a time-division multiplexed form to be output from the digital filter.

15. A filtering method according to claim 14, further comprising the step of:
separating said first and second filtered signal sequences in the time-division-multiplexed form to generate said first filtered signal sequence and said second filtered signal sequence.

16. A filtering method according to claim 15, wherein:
said filtering forms differential interpolation components of the discrete signal components of each said signal sequence.

17. A double interpolation method for generating a first double interpolated signal sequence and a second double interpolated signal sequence from an input signal which comprises a first and a second signal sequence being alternately time-division-multiplexed, said first and second signal sequences each comprising discrete signal components, said method comprising the steps of:
applying said input signal to a digital filter for outputting in response to said input signal a filter output comprising a first and a second filtered signal sequence being alternately time-division-multiplexed;
separating said filter output into said first filtered signal sequence and said second filtered signal sequence;
delaying said input signal to generate a delayed input signal; and
combining said first filtered signal sequence with said first signal sequence in said delayed input signal to generate said first double interpolated signal sequence, and combining said second filtered signal sequence with said second signal sequence in said delayed input signal to generate said second double interpolated signal sequence.

18. A double interpolation method according to claim 17, wherein:
the plurality of taps of said digital filter include a center tap and odd-numbered taps counted from said center tap have coefficients equal to zero.

19. A double interpolation method according to claim 18, wherein:
said filtering forms differential interpolation components of the discrete signal components of each said signal sequence.
